(19) United States
(12) Patent Application Publication
(10) Pub. No.: US 2013/0032085 A1
(43) Pub. Date: Feb. 7, 2013

(54) PLASMA ASSISTED HVPE CHAMBER DESIGN

(71) Applicants: Hiroji HANAWA, Sunnyvale, CA (US); Yuriy Melnik, Santa Clara, CA (US); Donald J.K. Olgado, Palo Alto, CA (US); Karl M. Brown, Santa Clara, CA (US); Son T. Nguyen, San Jose, CA (US); Kevin S. Griffin, Livermore, CA (US)

(72) Inventors: Hiroji HANAWA, Sunnyvale, CA (US); Yuriy Melnik, Santa Clara, CA (US); Donald J.K. Olgado, Palo Alto, CA (US); Karl M. Brown, Santa Clara, CA (US); Son T. Nguyen, San Jose, CA (US); Kevin S. Griffin, Livermore, CA (US)

(73) Assignee: Applied Materials, Inc., Santa Clara, CA (US)

(21) Appl. No.: 13/456,693

(22) Filed: Apr. 26, 2012

Related U.S. Application Data
(60) Provisional application No. 61/515,289, filed on Aug. 4, 2011.

(51) Int. Cl. C30B 25/14; C30B 25/02

(52) U.S. Cl. 117/103; 118/726

(57) ABSTRACT

Embodiments of the invention disclosed herein generally relate to a hydride vapor phase epitaxy (HVPE) deposition chamber that utilizes a plasma generation apparatus to form an activated precursor gas that is used to rapidly form a high quality compound nitride layer on a surface of a substrate. In one embodiment, the plasma generation apparatus is used to create a desirable group-III metal halide precursor gas that can enhance the deposition reaction kinetics, and thus reduce the processing time and improve the film quality of a formed group-III metal nitride layer. In addition, the chamber may be equipped with a separate nitrogen containing precursor activated species generator to enhance the activity of the delivered nitrogen precursor gases.

### CROSS-REFERENCE TO RELATED APPLICATIONS

This application claims the benefit of Provisional Patent Application Ser. No. 61/515,289, filed Aug. 4, 2011, and entitled “Plasma Assisted HVPE Chamber Design,” which is herein incorporated by reference.

### BACKGROUND OF THE INVENTION

1. Field of the Invention

Embodiments disclosed herein generally relate to a hydride vapor phase epitaxy (HVPE) chamber.

2. Description of the Related Art

As the demand for LEDs, LDs, transistors, and integrated circuits increases, the efficiency of depositing the Group-III metal nitride takes on greater importance. Therefore, there is a need in the art for an improved HVPE deposition method and an HVPE apparatus.

Group III-V films are finding greater importance in the development and fabrication of a variety of semiconductor devices, such as short wavelength light emitting diodes (LEDs), laser diodes (LDs), and electronic devices including high power, high frequency, high temperature transistors and integrated circuits. For example, short wavelength (e.g., blue/green to ultraviolet) LEDs are fabricated using the Group III-nitride semiconducting material gallium nitride (GaN). It has been observed that short wavelength LEDs fabricated using GaN can provide significantly greater efficiencies and longer operating lifetimes than short wavelength LEDs fabricated using non-nitride semiconducting materials, such as Group II-VI materials.

One method that has been used for depositing Group-III nitrides, such as GaN, is metal organic chemical vapor deposition (MOCVD). An alternate method that has been used to deposit Group-III nitrides is known as hydride vapor phase epitaxy (HVPE). In a conventional HVPE apparatus element, a hydride gas, such as HCl, reacts with the Group-III metal to form a precursor gas, which then reacts with a nitrogen precursor to form the Group-III metal nitride layer on the substrate. These chemical vapor deposition type methods are generally performed in a reactor having a temperature controlled environment to assure the stability of a first precursor gas, which contains at least one Group III element, such as gallium (Ga). A second precursor gas, such as ammonia (NH₃), provides the nitrogen needed to form a Group III-nitride. The two precursor gases are injected into a processing zone within the reactor where they mix and move towards a heated substrate in the processing zone. A carrier gas may be used to assist in the transport of the precursor gases towards the substrate. The precursors react at the surface of the heated substrate to form a Group III-nitride layer on the substrate surface. The quality of the film depends in part upon deposition uniformity, which, in turn, depends upon uniform delivery and mixing of the precursors across the substrate. Also, to maintain a desired processing gas concentration and fluid dynamic conditions in the chamber, it is common to continuously flow the precursors into the processing region of the chamber and out an exhaust port formed in the chamber. Thus any of the reaction byproducts and unreacted gases are exhausted from the chamber and sent to a waste collection system or scrubber. One will note that the process gases are often costly, and thus the amount of unreacted process gases that are wasted will greatly affects the cost-of-ownership of the deposition system. These factors are all important since they directly affect the cost to produce an electronic device and, thus, a device manufacturer's competitiveness in the marketplace.

Also, as the demand for LEDs, LDs, power delivery device, transistors, and integrated circuits increases, the efficiency, film quality and speed with which the layers are deposited takes on greater importance. Therefore, there is a need for an improved deposition apparatus and process that can provide a high deposition rate and high process efficiency, while having a consistent film quality over larger substrates and larger deposition areas.

### SUMMARY OF THE INVENTION

Embodiments disclosed herein generally relate to a hydride vapor phase epitaxy (HVPE) deposition chamber that utilizes a plasma generation apparatus to form an activated precursor gas that is used to rapidly and efficiently form a high quality compound nitride layer on a surface of a substrate. In one embodiment, the plasma generation apparatus is used to create a desirable group-III metal halide precursor gas that can enhance the deposition reaction kinetics, and thus reduce the processing time and improve the film quality of a formed group-III metal nitride layer. In one example, the plasma generation apparatus is used to create a desirable group-III metal halide precursor gas that contains gallium chloride (e.g., GaClₓ, where x=1, 2 or 3). In some cases, it is desirable to use the plasma generation apparatus to form a precursor gas that predominantly contains gallium monochloride (GaCl) versus gallium bichloride (GaCl₂) or gallium trichloride (GaCl₃). The HVPE deposition chamber may have one or more precursor sources coupled thereto that can utilize one or more of the methods and apparatus disclosed herein. When two or more separate precursor sources are coupled thereto, a single layer having a constant or varying composition or two or more separate layers may be deposited. For example, a gallium source and a separate aluminum source may be coupled to the processing chamber to permit gallium nitride and aluminum nitride to be separately deposited onto a substrate in the same processing chamber.

Embodiments of the invention generally provide a method of depositing a layer on one or more substrates, comprising inserting one or more substrates into a processing region of a processing chamber, the processing chamber comprising a precursor deliver source comprising a crucible having a material collection region, wherein the crucible is disposed in a source region of the precursor deliver source, a first electrode disposed in the material collection region of the crucible, and a power source coupled to the first electrode, flowing a first gas into the source region, heating a source material disposed in the material collection region, wherein the first electrode is in electrical communication with the heated source material, electrically biasing the first electrode using the power source to form a plasma over a surface of the heated source material, wherein the plasma comprises at least a portion of the first gas, and flowing a second gas into the source region to cause at least a portion of the activated precursor gas to flow into the processing region of the processing chamber.

Embodiments of the invention may further provide an apparatus for depositing a layer on one or more substrates, comprising a chamber body comprising one or more chamber walls that define a chamber processing region, a precursor deliver source comprising a crucible having a first material collection region, wherein the crucible is disposed in a source region of the precursor deliver source, a first electrode disposed in the first material collection region of the crucible, a power source coupled to the first electrode, and gas delivery source configured to deliver a halogen gas to the source region, and a gas distribution element that is positioned to distribute a process gas into the chamber processing region from a process gas source.

Embodiments of the invention may further provide an apparatus for depositing a layer on one or more substrates, comprising a chamber body comprising one or more chamber walls that define a chamber processing region, a precursor delivery source comprising a crucible disposed in a source region of the precursor deliver source having a first material collection region, a first electrode disposed in the first material collection region of the crucible, a power source coupled to the first electrode, and gas delivery source configured to deliver a halogen gas to the source region, and a gas distribution element positioned to distribute a process gas into the chamber processing region.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic view of an HVPE processing chamber according to one embodiment.

FIG. 2 schematic isometric cross-sectional view of a plasma generation apparatus according to another embodiment.

FIG. 3 schematic isometric cross-sectional view of an alternate version of the plasma generation apparatus according to another embodiment.

FIG. 4 is a schematic view of an HVPE processing chamber according to one embodiment.

FIG. 5 is a schematic view of an alternate version of the HVPE processing chamber illustrate in FIG. 1 according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the invention disclosed herein generally relate to a hydride vapor phase epitaxy (HVPE) deposition chamber that utilizes a plasma generation apparatus to form an activated precursor gas that is used to rapidly form a high quality compound nitride layer on a surface of a substrate. Many electronic devices, such as power transistors, as well as optical and optoelectronic devices, such as light-emitting diodes (LEDs), may be fabricated from layers of group-III metal nitride films. In one embodiment, the plasma generation apparatus is used to create a desirable group-III metal halide precursor gas that can enhance the deposition reaction kinetics, and thus reduce the processing time and improve the film quality of a formed group-III metal nitride layer, such as gallium nitride (GaN), aluminum nitride (AlN) or indium nitride (InN) or combinations thereof. It is also believed that the use of a plasma to form a precursor gas will improve the efficiency of the precursor gas formation process, and thus less of the often costly reactive gases are needed to form a desired amount of the precursor gas. In one example, the plasma generation apparatus is used to create a desirable group-III metal halide precursor gas that contains gallium chloride (e.g., GaClₓ, where x=1, 2 or 3). In some cases, it is desirable to use the plasma generation apparatus to form a precursor gas that predominantly contains gallium monochloride (GaCl) versus gallium trichloride (GaCl₃), or gallium bichloride (GaCl₂), since it believed that the formation of the less thermodynamically stable GaCl containing precursor gas will increase the speed with which the deposition reaction with a nitrogen containing precursor will occur to more rapidly form a group-III metal nitride (e.g., GaN) containing layer on the substrate. The geometry of the chamber may be set such that the precursor gas formed using the plasma generation apparatus and the other reactive gases are introduced into the chamber separately to avoid unwanted deposition on the gas delivery system parts. In addition, the chamber may be equipped with a separate device that can form an activated nitrogen containing precursor gas.

In general, an HVPE chamber can have one or more precursor sources coupled thereto, that can be used to form at least two separate layers on a substrate, or form a layer that has a graded composition. In one configuration of the HVPE chamber, a plasma assisted gallium source and a separate aluminum source may be coupled to the chamber to permit a gallium nitride layer and aluminum nitride layer to be separately deposited onto a substrate in the same HVPE processing chamber. In one embodiment, five precursor sources may be coupled to the HVPE chamber. Such precursor sources are generally capable of separately forming and dispensing precursor gases that contain gallium, indium, aluminum, silicon, and magnesium, which may be plasma activated.

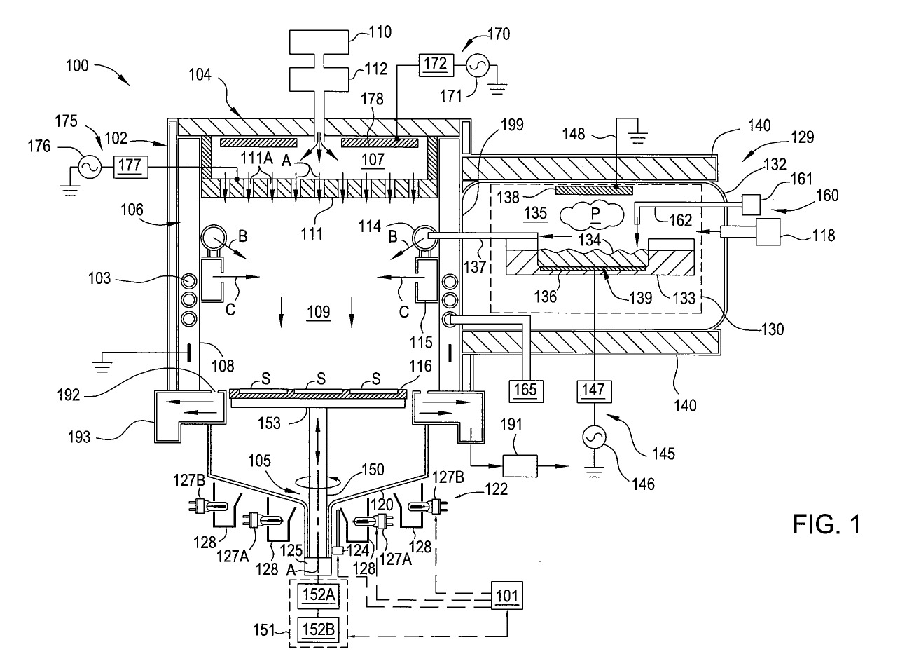

FIG. 1 is a schematic view of an HVPE apparatus 100 according to one embodiment of the invention. The HVPE apparatus 100 includes a chamber 102, a chamber lid assembly 104, one or more precursor generation regions 129, a lamp module 122, a lower dome 120, a lift assembly 105 and a controller 101. The chamber lid assembly 104 generally comprises a gas distribution showerhead 111, which is disposed within an opening in the walls 106 of the chamber 102, and a gas source 110. A processing gas delivered from the gas source 110 flows into the processing region 109 of the chamber 102 through a plurality of holes 111A formed in the gas distribution showerhead 111. In one embodiment, the gas source 110 is adapted to deliver a nitrogen containing compound to the processing region 109. In one example, the gas source 110 is adapted to deliver the nitrogen containing precursor gas, which may include a gas comprising ammonia (NH₃) and/or hydrazine (N₂H₄). In one configuration, an inert gas such as helium or diatomic nitrogen may be introduced as well either through the gas distribution showerhead 111, or through the walls 108 of the chamber 102 (e.g., reference label “C”), and into the processing region 109. An energy source 112 may be disposed between the gas source 110 and the gas distribution showerhead 111. In one embodiment, the energy source 112 may comprise a remote plasma source (RPS), a heater, or other similar type device that is adapted to form radicals and/or break-up the gas from the gas source 110, so that the nitrogen from the nitrogen containing gas is more reactive.

In one embodiment of the chamber lid assembly 104, a source assembly 170 is disposed within a portion of the chamber lid assembly 104 to provide energy to the gases delivered to the processing region 109 through the showerhead 111. In one configuration of the source assembly 170, an RF power source 171 and an RF match 172 are electrically coupled to an electrode 178 that is disposed in the showerhead 111. RF power delivered to the electrode 178 from the RF power source 171 can be used to excite the gas(es) flowing through a plenum 107 formed in the showerhead 111, before they enter the processing region 109. The excited gases are used to enhance the deposition process occurring on the substrates “S” disposed in the processing region 109.

In one configuration of the chamber 100, heating of one or more substrates “S” disposed in the processing region 109 is accomplished by directly or indirectly heating the substrates “S” using a lamp module 122 that is disposed below a susceptor 153 and an optically transparent lower dome 120 (e.g., quartz dome). In one configuration, the lamps 127A, 127B in the lamp module 122 deliver heat to a substrate carrier 116 and/or the susceptor 153 that then deliver the received energy to the one or more substrates “S” disposed thereon. The lamp module 122, which may comprise arrays of lamps 127A, 127B and reflectors 128, is generally the main source of heat for the processing chamber 102. While shown and described as a lamp module 122, it is to be understood that other heating sources may be used. Additional heating of the processing chamber 102 may be accomplished by use of a heater assembly 103 (e.g., cartridge heater) embedded within the walls 106 of the chamber 102. In one configuration, the heater assembly 103 comprises a series of tubes that are coupled to a fluid type heat exchanging device 165. A thermocouple (not shown) may be used to measure the temperature of the walls 106 of processing chamber, and one or more pyrometers 124 may be used to monitor the temperature of the carrier 116 and substrates “S”. Output from the thermocouple and the one or more pyrometers 124 are fed back to a controller 101, so that the controller 101 can control the output of the heater assembly 103 and the arrays of lamps 127A, 127B based upon the received temperature readings. The lift assembly 105, which comprises an actuator assembly 151, is configured to position and rotate the susceptor 153, substrate carrier 116 and substrates “S” to help control the temperature uniformity of the substrates “S” during processing. A vertical lift actuator 152A and a rotation actuator 152B, which are contained in the actuator assembly 151, are used to position and rotate the substrates “S” in the processing region 109, and are controlled by the controller 101.

During processing, a first precursor gas from the first gas source 110 and a second precursor gas from the one or more precursor generation regions 129 are both delivered to the processing region 109 of the chamber 100, so that the interacting gases can form a layer having a desirable composition on the one or more substrates “S” disposed in the processing region 109. The one or more precursor generation regions 129 may be configured to form metal halide containing precursor gases, such as gallium, indium and/or aluminum halide containing precursor gases. It is to be understood that while reference will be made to two precursors, more or less precursors may be delivered as discussed above. In one embodiment, the precursor delivered from the one or more precursor generation regions 129 comprises gallium, which is formed from a source material 134 that is in a liquid form. In another embodiment, the precursor delivered from the one or more precursor generation regions 129 comprises aluminum, which is present in the precursor generation region 129 in a solid form. In one embodiment, the precursor may be formed and delivered into the processing region 109 of the chamber 102 by flowing a reactive gas into the source processing region 135 of the precursor generation region 129 from a process gas source 118, generating plasma over the source material 134 and then delivering the formed plasma activated metal halide gas from the source processing region 135 to the processing region 109 of the chamber 102 by use of a push gas (e.g., nitrogen (N₂)). The activated precursor gas can be delivered from the source processing region 135 of the precursor generation region 129 to a precursor delivery gas distribution element 114 via the delivery tube 137 (see arrow “B”). As will be discussed further below, in some configurations it is desirable to minimize the length of the delivery tube 137 and/or distance between the crucible 133 and the substrates to assure that a high percentage of still active activated precursor gas is delivered into the processing region 109 and/or minimize or prevent the condensation of the created precursor gases in the delivery tube 137. One will note that the percentage of activated gas atoms, which leave the region of the source processing region 135 in which the plasma is formed, will decrease with time due to loss of the energy imparted to the gas atoms by the plasma to the walls or other gas atoms. In some embodiments, a separate cleaning gas distribution element 115 is also used to deliver a cleaning gas “C”, such as a halogen gas (e.g., F₂, Cl₂), to the processing region 109 to remove any unwanted deposition on the chamber 100 process kit parts during one or more phases of the deposition process.

During processing, regions of the chamber 102 may be maintained at different temperatures to form a thermal gradient that can provide a gas buoyancy type mixing effect. For example, the processing gasses (e.g., nitrogen based gas) delivered from the gas source 110 are introduced through the gas distribution showerhead 111 at a temperature between about 450° C. and about 550° C. The chamber walls 106 may have a temperature of about 600° C. to about 700° C. The susceptor 153 may have a temperature of about 1050 to about 1150° C. In one example, the GaN film is formed over the sapphire substrate by a HVPE process at a susceptor 153 temperature between about 700° C. to about 1100° C. Thus, the temperature difference within the chamber 102 may permit the gas to rise within the chamber 102 as it is heated and then fall as it cools. The rising and falling of the gases may cause the nitrogen containing precursor gas “A” and the activated precursor gas(es) “B” to mix. Additionally, the buoyancy effect may reduce the amount of gallium nitride or aluminum nitride that deposits on the walls 106 because of the mixing.

### Precursor Source Assemblies

In one embodiment of the HVPE apparatus 100, the precursor generation region 129 comprises a chamber 132, a plasma generation apparatus 130, a source material 134, a source assembly 145, a process gas source 118, a feed material source 160 and a heater assembly 140. The chamber 132 generally comprises one or more walls that enclose a source processing region 135. The one or more walls generally comprise a material that is able to withstand the high processing temperatures typically used to form the plasma activated precursor gas, and also maintain their structural integrity when the processing pressure within the source processing region 135 is reduced to pressures as low as about 1 Torr by use of the chamber pump 191. Typical wall materials may include quartz, silicon carbide (SiC), boron nitride (BN), stainless steel, or other suitable material. In one configuration, the chamber pump 191 is coupled to the source processing region 135 through the delivery tube 137 and ports 192 formed in the exhaust plenum 193 found in the chamber 102.

In one embodiment of the precursor generation region 129, as illustrated in FIG. 1, the plasma generation apparatus 130 comprises a crucible 133 that is configured to retain an amount of source material 134 that is disposed in a material collection region 139 formed in the crucible 133. The source material 134 may comprise a metal, such as a group III metal (e.g., gallium (Ga), aluminum (Al), indium (In)). An activated precursor gas is created by the formation of a plasma over the surface of the source material 134 using a process gas delivered from the process gas source 118. The process gas source 118 is generally configured to deliver one or more process gases to the source processing region 135 of the chamber 132 to form the activated group-III metal halide precursor gas therein. In one configuration, the process gas source 118 is configured to deliver a halogen gas (e.g., Cl₂, F₂, I₂, Br₂), or hydrogen halides (e.g., HCl, HBr, Hl), and a push gas (e.g., N₂, He, H₂, Ar) that are used to form the group-III metal halide precursor gas (e.g., GaClₓ, InClₓ, AlClₓ) and push the formed precursor gas into the processing region 109 of the chamber 102. The plasma generation apparatus 130 generally includes one or more devices that are adapted to deliver energy to the source material 134 and/or process gases disposed in the processing region 135 of the precursor generation region 129, so that an activated precursor gas can be formed from the source material 134. The one or more device may include capacitively coupled, or inductively coupled, DC, RF and/or microwave sources that are configured to deliver energy to the source material 134 and/or process gases disposed in the processing region 135 of the precursor generation region 129. In general, a plasma, which is a state of matter, is created in the processing region 135 by the delivery of electrical energy or electromagnetic waves (e.g., radio frequency waves, microwaves) to the process gas to cause it to at least partially breakdown to form ions, electrons and energized neutral particles (e.g., radicals). In one example, a plasma is created in the processing region 135 by the delivery electromagnetic waves from the source assembly 145 at frequencies less than about 100 gigahertz (GHz). In another example, the one or more electromagnetic sources are each configured to deliver electromagnetic energy at a frequency between about 0.4 kilohertz (kHz) and about 200 megahertz (MHz), such as a frequency of about 162 megahertz (MHz). One will note that the term “chemical element” as used herein is intended to define a pure chemical substance consisting of one type of atom found in the period table.

The crucible 133 generally comprises an electrically insulating material that can withstand the high processing temperatures that are commonly required to form a group-III metal halide precursor gas, and at least partially encloses the material collection region 139, which is adapted to hold the source material 134. In one configuration, the crucible 133 is formed from quartz, boron nitride (BN), silicon carbide (SiC), or combinations thereof.

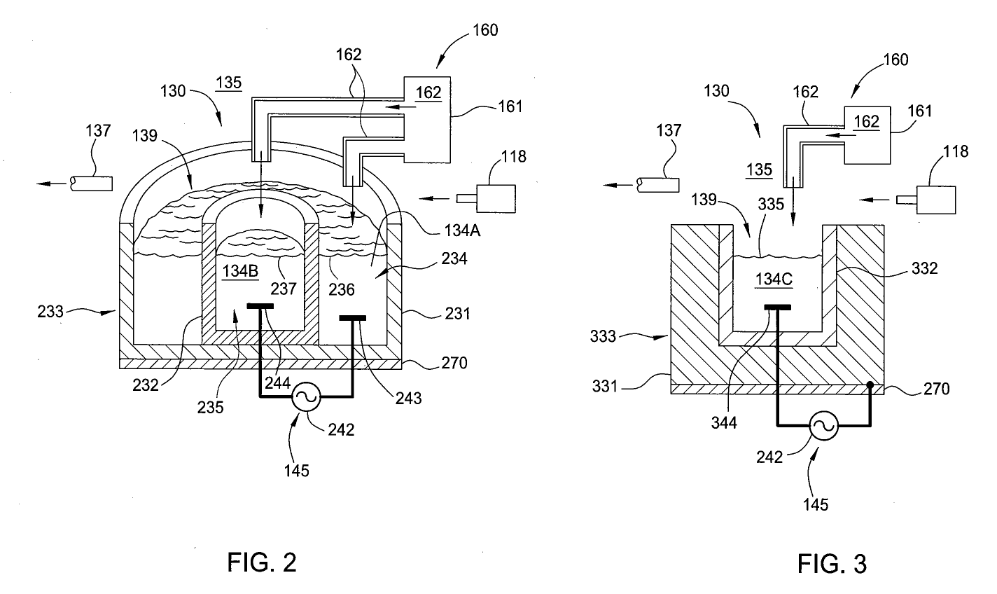

In one configuration of the crucible 133, an electrode 136 is disposed within the material collection region 139, and is electrically coupled to the source material 134, so that a plasma can be formed in the source processing region 135 over the surfaces of the source material 134. The plasma can be formed by delivering RF energy from a power source 146 to the electrode 136, thus RF biasing the source material 134 relative to a separate grounded electrode 138. In one example, during processing the power source 146 is configured to deliver a high voltage moderate frequency electric power to the electrode 136 that is disposed in the source material 134. In one example, the power delivered to the electrode 136 is delivered at a frequency less than about 500 kHz and at a peak-to-peak voltage that is between about 5 and 20 kVolts. In another example, the power delivered to the electrode 136 is delivered at a frequency less than about 40 kHz and at a peak-to-peak voltage that is between about 10 and 20 kVolts. In another example, the power delivered to the electrode 136 is delivered at a frequency less than about 13.56 MHz and at a peak-to-peak voltage that is between about 700 Volts and 1 kVolt, when the pressure in the processing region is between about 1 mTorr and 10 Torr. The electrical energy delivered to the source material 134 causes the process gas(es) (e.g., halogen gases) disposed over the surfaces of the source material 134 to breakdown and form a plasma “P” (FIG. 1). The formed plasma thus enhances the formation and activity of the created group-III metal halide precursor gas, which is formed by the interaction of the plasma activated process gas(es). It is believed that by directly biasing the source material 134 relative to a second electrode that a more efficient and controlled generation of the activated precursor gas can be created, due to the plasma interaction with surface of the biased source material 134. The plasma bombardment and interaction with the source material 134 is believed to be important during the precursor formation process, since the bombardment of the surface of the source material by the energetic ions and gas atoms formed in the plasma will tend to cause the formed precursor gas components (e.g., GaCl, GaCl₂, GaCl₃, AlCl₃) to go into the gas phase leaving a fresh unreacted surface exposed (e.g., liquid Ga, solid Al) so that it can then react with gas atoms (e.g., Cl₂) found in the plasma. In one configuration, it is desirable to deliver energy to the source material so that the power density at the surface of the source material is between about 30 Watts/in² to about 2 kWatts/in². To assure that the source material 134 is in a desired physical state, such as a liquid or a solid, during the group-III metal halide precursor gas formation process, a heater assembly 140 (e.g., resistive heating elements, lamps), or a separate crucible heater assembly 270 (FIGS. 2-3), is used to heat the source material 134 disposed in the material collection region 139 to a desired temperature.

A group-III metal halide precursor gas formation process may comprise, for example, heating a source material that comprises gallium (Ga) to a temperature greater than about 29° C., flowing a process gas that comprises chlorine (Cl₂) into the source processing region 135 to achieve a pressure of between about 150 and 450 Torr and forming a plasma over the surface of the source material by applying about a 10 kV peak-to-peak bias at a frequency less than about 500 kHz between the electrodes 136 and 138 to form an activated gallium chloride containing gas. In one example of the process, a source material that comprises gallium (Ga) is heated to a temperature between about 500 and 800° C., a process gas comprising between about 5 and about 70% chlorine (Cl₂) gas diluted in nitrogen is delivered into the source processing region 135 to achieve a pressure of about 360-400 Torr and a plasma is formed over the surface of the source material by applying about a 10 kV peak-to-peak bias at a frequency between about 20-40 kHz to form a precursor gas comprising substantially gallium monochloride (GaCl) and/or gallium monochloride (GaCl) radicals.

As discussed above, the pressure in the source processing region 135 during the activated group-III metal halide precursor gas formation process may be between about 1 Torr and about 760 Torr, such as between about 150 Torr and about 450 Torr, or between about 250 Torr and about 400 Torr. However, in some cases, a lower processing pressure may be advantageous to provide an additional process variable that can be used to control the precursor formation reaction. By controlling the pressure in the processing region, and partial pressure of the reactive gas(es), so that the gases disposed therein are in gas flow regime that is more diffusion limited the reactive gas and source material interaction can be better controlled. In this case, the pressure in the source processing region 135 during the group-III metal halide precursor gas formation process may be between about 1 mTorr and about 10 Torr, such as between about 10 mTorr and about 100 mTorr. When using a lower group-III metal halide precursor gas formation processing pressure is utilized, it may be desirable to use a higher frequency source power (e.g., MHz) versus a lower frequency source power (e.g., kHz).

Since the formation of the group-III metal halide precursor gas depletes the amount of source material 134 found in the crucible 133, it is desirable to assure that the amount of source material 134 disposed in the material collection region 139 doesn't run out during processing. Therefore, in one embodiment, a feed material source 160 may be used to assure that a desired amount of the source material is always disposed in the material collection region 139 of the crucible 133. The feed material source 160 generally comprises a delivery assembly 161 and a delivery tube 162 that is adapted to deliver an amount of the source material 134 to the source material collection region 139 of the crucible 133. The delivery assembly 161 will generally include a source material retaining region (not shown) that is adapted to retain and then deliver a desired amount of the source material 134 to the source material collection region 139 by use of a pressurized gas source (not shown) or mechanical metering pump (not shown). In some configurations, the delivery assembly 161 is also adapted to heat the source material 134 prior to its deliver into the source material collection region 139 by use of a resistive heater (not shown), lamp (not shown) or inductive heater (not shown). In some configurations, the delivery assembly 161 is adapted to heat the source material 134, such as gallium (Ga) or indium (In), to a liquid state prior to its delivery into the source material collection region 139.

In one embodiment of the precursor generation region 129, as illustrated in FIG. 2, the plasma generation apparatus 130 comprises a crucible 233 that is configured to separately retain an amount of source material 134A and an amount of source material 134B. As illustrated in FIG. 2, the crucible 233 generally comprises a first material collection region 234 and a second material collection region 235 that are each adapted to separately retain an amount of the source material. In one configuration the source material 134A and source material 134B are compositionally the same material, such a liquid gallium (Ga). However, in some cases the source material 134A and source material 134B are compositionally different materials.

The crucible 233 generally comprises a first wall 231 that at least partially defines the first material collection region 234 and a second wall 232 that at least partially defines the second material collection region 235. The first and second walls 231, 232 generally comprise an electrically insulating material that can withstand the high processing temperatures that are commonly required to form a group-III metal halide precursor gas. In one configuration, the crucible 233 is formed from quartz, boron nitride (BN), silicon carbide (SiC), or combinations thereof.

In one configuration of the crucible 233, a first electrode 243 is electrically coupled to the source material 134A and a second electrode 244 is electrically coupled to the source material 134B, so that a plasma can be formed in the source processing region 135 over the surfaces 236, 237 of the source materials 134A, 134B, respectively. The plasma can be formed by applying an RF bias to the first electrode 243 and source material 134A relative to the second electrode 244 and source material 134B from a power source 242 found in the source assembly 145. In one example, during processing the power source 242 is configured to deliver a high voltage moderate frequency electric power to the electrodes 243 and 244. In one example, the power delivered between the electrodes 243, 244 is delivered at a frequency less than about 500 kHz and at a peak-to-peak voltage that is between about 5 and 15 kVolts. The electrical energy delivered to the source material 134A and source material 134B causes the process gas over the surfaces 236, 237 of the source materials 134A, 134B to breakdown and form a plasma that is used enhance the formation and activity of the created group-III metal halide precursor gas. To assure that the source material 134A, 134B is in the desired physical state, such as a liquid or solid, during the group-III metal halide precursor gas formation process, the heater assembly 140 (e.g., resistive heating elements, lamps), or a separate crucible heater assembly 270, may be used to heat the source material 134A, 134B to a desired temperature.

In some cases, the plasma activated precursor gas contains ions and/or radicals. In one example, during the group-III metal halide precursor gas formation process the source materials 134A, 134B, which comprise liquid gallium, is heated to a temperature of greater than about 29° C., a process gas comprising between about 5 and about 70% chlorine (Cl₂) gas diluted in nitrogen is delivered into the source processing region 135 to achieve a pressure of about 360-400 Torr and a plasma is formed over the surface of the source materials by applying about a 10 kV peak-to-peak bias at a frequency less than about 500 kHz between the electrodes 243 and 244, such as between about 20-40 kHz, to form an activated gallium chloride containing gas, such as a precursor gas comprising substantially gallium monochloride (GaCl). In one example, the pressure in the source processing region 135 during the group-III metal halide precursor gas formation process may be between about 1 Torr and about 760 Torr, such as between about 150 Torr and about 400 Torr. In another example, the pressure in the source processing region 135 during the group-III metal halide precursor gas formation process may be between about 1 mTorr and about 10 Torr, such as between about 10 mTorr and about 100 mTorr.

It is believed that by biasing one amount of a source material (e.g., source material 134A) relative to a second amount of a source material (e.g., source material 134B) that a more efficient generation of the activated precursor gas can be created by the direct coupling of the delivered electrical energy to the conductive source materials 134A, 134B themselves. The delivery of the electrical energy directly to the electrically isolated amounts of source material will cause ions and/or radicals in the generated plasma to bombard and/or interact with the surfaces 236, 237 of the source materials, and thus enhance the formation of the activated precursor gas. The bombardment of the surface of the source material can also help assure that any previously reacted material (i.e., formed precursor gas) is readily removed from the surface of the source material due to the added energy imparted by the bombarding ions or radicals, thus increasing the likelihood that the unreacted source material will be exposed and react with the ions, radicals and/or other gases disposed in the source processing region 135. In one example, the reaction to form a gallium chloride containing precursor may include one or both of the following reactions.

(1) 2Ga (I)+Cl₂ (g)→2GaCl (g)

(2) 2Ga (I)+3Cl₂ (g) 2GaCl₃ (g)

In another example, the reaction to form an aluminum chloride or Indium chloride containing precursor may include the following reaction.

(3) 2Al (s)+3Cl₂ (g) 2AlCl₃ (g)

(4) 2In (I)+3Cl₂ (g) 2InCl₃ (g)

It is believed that by use of a plasma activated process gas that a desirable group-III metal halide precursor gas can be created versus conventional thermal HVPE precursor generation processes, which are known in the art. The use of a plasma to form a precursor gas will generally improve the efficiency of the precursor gas formation process, and thus less of the often costly reactive gases (e.g., Cl₂) are needed to form a desired amount of the precursor gas. In one example, as discussed above, it may be desirable to form a precursor gas that primarily contains gallium monochloride (GaCl) versus a gallium trichloride (GaCl₃). It is believed that the formation of the less stable GaCl containing precursor gas versus the GaCl₃ containing precursor gas will increase the speed with which the deposition reaction with a nitrogen containing precursor, such as ammonia (NH₃) and/or and hydrazine (N₂H₄), will occur to more rapidly form a group-III metal nitride (e.g., GaN) containing layer on a surface of the substrate. During processing the formed group-III metal halide precursor gas is then delivered into the processing region 109 of the chamber 102 by flowing a push gas (e.g., nitrogen (N₂)) from the process gas source 118 which causes the formed precursor gas to flow into the delivery tube 137 and out into the processing region 109 (see arrow “B”).

In one embodiment of the precursor generation region 129, a feed material source assembly 160 is adapted to deliver an amount of a source material to the source material collection regions 234, 235 formed in the crucible 233. As similarly discussed above, a delivery assembly 161 is generally adapted to retain and deliver a desired amount of the source material to the source material collection regions 234, 235 formed in the crucible 233 to minimize the chamber downtime and time required to refill the crucible 233.

In another embodiment of the precursor generation region 129, as illustrated in FIG. 3, the plasma generation apparatus 130 comprises a crucible 333 that is configured to retain an amount of source material 134C. As illustrated in FIG. 2, the crucible 333 generally comprises a material collection region 335 that is adapted to retain an amount of the source material 134C. In one configuration, the crucible 333 comprises an insulating wall 332, which at least partially defines the material collection region 335, and a conductive element region 331. The insulating wall 332 generally comprises an electrically insulating material that can withstand the high processing temperatures that are commonly required to form a group-III metal halide precursor gas. In one configuration, the insulating wall 332 is formed from quartz, boron nitride (BN), silicon carbide (SiC), or combinations thereof. In general, the conductive element region 331 comprises a conductive material that is adapted to withstand the high processing temperatures found in the processing region, and may generally comprise a refractory metal (e.g., W, Co, Ir), conductive metal oxide material or other suitable conductive material.

In one configuration of the crucible 333, the power source 242 is coupled to an electrode 344 that is electrically coupled to the source material 134C and to a conductive element region 331, so that a plasma can be formed in the source processing region 135 over the surface of the source materials 134C. In one example, during processing the power source 242 in the source assembly 145 is configured to deliver a high voltage moderate frequency electric power to the electrode 344 relative to the conductive element region 331 to cause the process gas disposed over the surface of the source materials 134C to breakdown and form a plasma, which is used to enhance the formation and activity of the created group-III metal halide precursor gas. During processing the formed group-III metal halide precursor gas is then delivered into the processing region 109 of the chamber 102 by flowing a push gas (e.g., nitrogen (N₂)) from the process gas source 118, which causes the formed precursor gas to flow into the delivery tube 137 and out into the processing region 109 (see arrow “B”).

To assure that the source material 134C is in the desired physical state, such as a liquid or solid, during the group-III metal halide precursor gas formation process, the heater assembly 140, or a separate crucible heater assembly 270 (e.g., resistive heating element, lamps), may be used to heat the source material 134C disposed in the first material collection region 335. In this configuration, the spacing between the source material 134C and the conductive element region 331 can be controlled to reliably form a plasma over the surface of the source material 134C.

In one embodiment of the precursor generation region 129, a feed material source assembly 160 is adapted to deliver an amount of a source material to the source material collection region 335 formed in the crucible 333. As similarly discussed above, a delivery assembly 161 is generally adapted to retain and deliver a desired amount of the source material to the source material collection region 335 formed in the crucible 333 to minimize the chamber downtime and time required to refill the crucible 333.

It has been found that the control of the pressure in the source processing region 135 of the precursor generation region 129 and the control of the temperature of the source material(s) is important to: (1) control the composition or properties of the activated precursor gas (e.g., GaCl to GaCl₃ ratio) and (2) assure that the formation of the activated precursor gas can be reliably formed and delivered to the substrates “S” disposed in the processing region 109 for extended periods of time. Since the plasma energy added to the source material(s) allows a precursor gas to be formed at temperatures below its vapor pressure, a plasma generated precursor gas formed in this way will tend to condense on the various chamber parts disposed in the source processing region 135 of the precursor generation region 129. A formed precursor gas that condenses in the chamber will generally reduce the efficiency of the precursor formation process, cause clogging of the gas delivery components and generate particles. Therefore, the control of the temperature of the source processing region 135 components and gas delivery components, such as delivery tube 137 and gas distribution element 114, at a desirable processing pressure is important to prevent condensation. In one example, to avoid condensation a gallium containing precursor is generated by flowing chlorine gas at a flow rate between about 5 sccm to about 500 sccm over liquid gallium maintained at a temperature between 200° C. to about 1000° C., while maintain the pressure in the processing region 135 at between about 150 and about 500 Torr. In one example, the liquid gallium, precursor delivery components and chamber components may be maintained at a temperature of between about 500° C. and 900° C. In one example, the liquid gallium, precursor delivery components and chamber components may be maintained at a temperature of about 800° C.

It has also been found that the generation and condensation of the precursor gas can also limit one's ability to reliably control its generation using a plasma, due to the electrically conductive nature of the formed and condensed group-III precursor gases that can create a conductive path between the biased electrodes, and thus create an electrical “short” that will extinguish the formed plasma. Referring to FIG. 2, in one example, a conductive path can be created between the source material 134A and source material 134B over the surface of the wall 232, due to the formation of a continuous layer of the generated and condensed group-III precursor gas. Therefore, it is desirable to assure that the source material(s) be maintained at a temperature greater than the vaporization temperature at a given activated precursor gas generation processing pressure. The control of the temperature of the source material(s) disposed in the crucible (e.g., reference numerals 133, 233 or 333) can be controlled by use of the heater 270, and also the control the temperature of the other precursor generation region 129 chamber components can be completed by use of the heater 140.

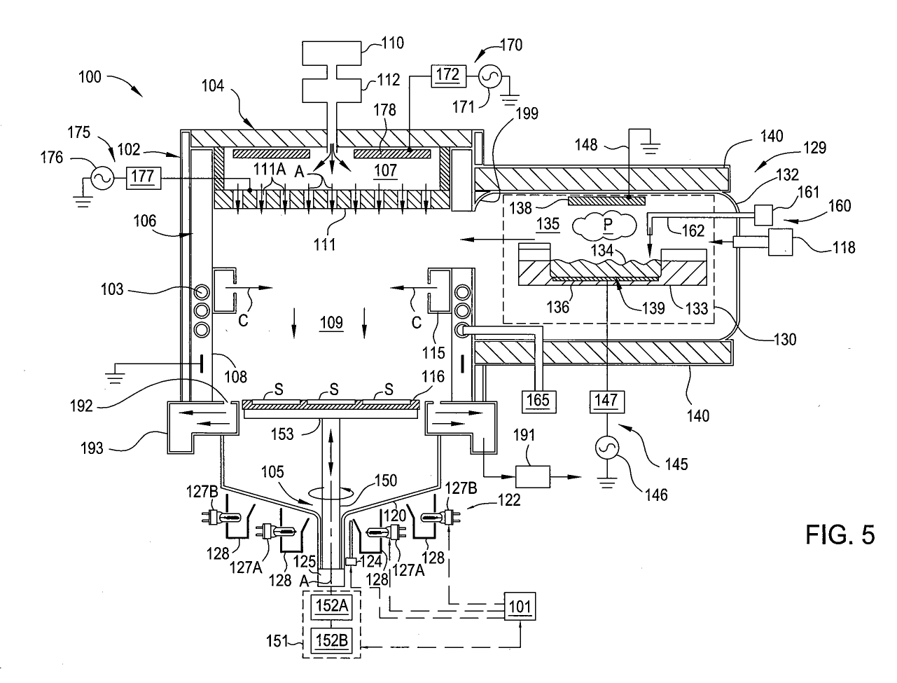

In one configuration, it is desirable to minimize the length of the delivery tube 137 and/or distance between the crucible (e.g., reference numerals 133, 233, 333) and the substrates. Therefore, in one embodiment of the HVPE apparatus 100, to minimize or prevent the condensation of the created precursor gas, a crucible is disposed in the processing region 109 of the chamber 100 (not shown). In one configuration, the precursor generation regions 129 may each be disposed in an adjoining region of the chamber 102 that will not block or disturb the flow of gases passing through the showerhead 111 (FIG. 1) and onto the surface of the substrate W, while still being able to form and deliver the formed precursor gas(es) to the substrates “S.” Referring to FIG. 5, which is similar to FIG. 1 except that an adjoining region of the chamber 102 has been formed by the removal at least a portion of the wall 199 and wall 106, thus allowing the activated precursor gas to be formed in region of the chamber that is open to and/or is a part of the processing region 109.

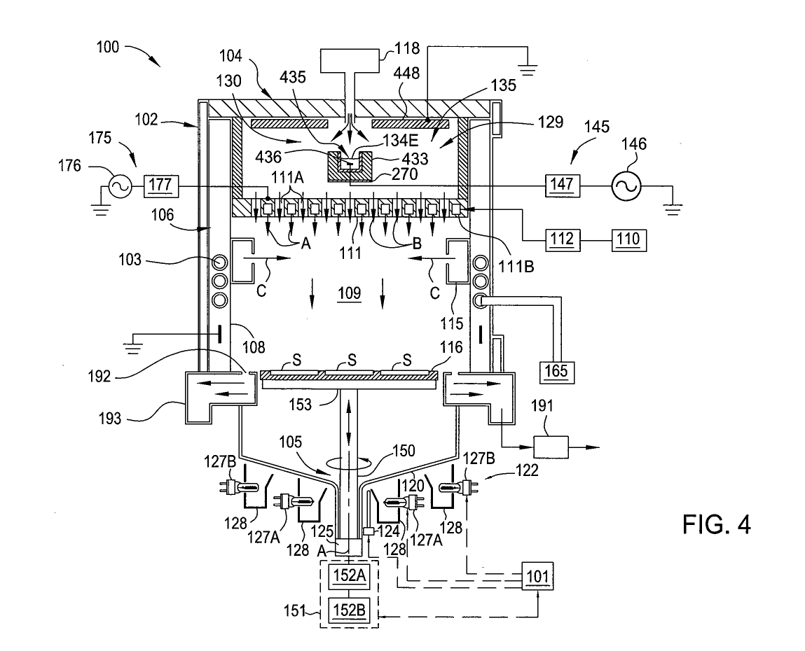

In one embodiment of the HVPE apparatus 100, as illustrated in FIG. 4, a precursor generation region 129 is disposed within a portion of the chamber lid assembly 104 to uniformly deliver an activated precursor gas to the processing region 109 through holes 111A in the showerhead 111 (see flow “B”). In one configuration of the precursor generation region 129, as illustrated in FIG. 4, the plasma generation apparatus 130 comprises a crucible 433 that is configured to retain an amount of source material 134E that is disposed in a material collection region 435 formed in the crucible 433. The crucible 433 generally is similar to any of the crucible configurations discussed above. The activated precursor gas is created by the formation of a plasma over the surface of the source material 134E using a process gas delivered from the process gas source 118. The process gas source 118 is generally configured to deliver one or more gases to the source processing region 135 to form the activated group-Ill metal halide precursor gas therein. In one configuration, the process gas source 118 is configured to deliver a halogen gas (e.g., Cl₂, I₂, Br₂), or hydrogen halides (e.g., HCl, HBr, Hl), and a push gas (e.g., N₂, H₂, Ar) that are used to form the group-III metal halide precursor gas and push the formed precursor gas into the processing region 109 of the chamber 102 through the holes 111A of the showerhead 111.

In one configuration of the crucible 433, an electrode 436 is disposed within the material collection region 435, and is electrically coupled to the source material 134E, so that a plasma can be formed in the source processing region 135 over the surfaces of the source material 134E. The plasma can be formed by delivering RF energy from a power source 146 to the electrode 436, thus RF biasing the source material 134 relative to a separate grounded electrode 448. To assure that the source material 134 is in a desired physical state, such as a liquid or a solid, during the group-III metal halide precursor gas formation process, the heater assembly 103, or a separate crucible heater assembly 270 (FIGS. 2-3), is used to heat the source material 134E disposed in the material collection region 435 to a desired temperature.

In one embodiment of the chamber lid assembly 104, as illustrated in FIG. 4, a nitrogen containing precursor gas, which may include a gas comprising ammonia (NH₃) and/or hydrazine (N₂H₄), is delivered into the processing region 109 through a separate plenum 111B formed in the gas distribution showerhead 111 (see flow “A”). In one embodiment, an energy source 112, which may comprise remote plasma source (RPS), a heater or other similar device, is configured to form radicals and/or break-up the gas delivered to the processing region 109 from the gas source 110 to increase the reactivity of the delivered nitrogen containing precursor gases.

In one embodiment of the chamber lid assembly 104, as illustrated in FIGS. 1 and 4, a source assembly 175 is adapted to provide RF energy to the gases disposed in the processing region 109 of the chamber 100. The source assembly 175 may comprise an RF power source 176 and an RF match 177 that are electrically coupled to an electrode (not shown) that is disposed in the showerhead 111. In one example, the showerhead 111 comprises a metallic material, such as tungsten (W) or other refractory metal that is able to withstand the high processing temperatures. RF power delivered to the electrode from the RF power source 176 can be used to excite the gas(es) disposed in the processing region 109, to increase the activity of the gases disposed over the surface of the substrates “S,” and thus enhance the deposition process. In one embodiment of the activated precursor gas formation process, a gallium trichloride gas (GaCl₃), which is generated and delivered to the processing region 109 from a precursor generation region 129, is transformed into an activated gallium monochloride (GaCl) by use of the plasma formed in the processing region 109 by the RF power source 176 components. In one example, the RF power source 176 is configured to provide between about 1-5 kWatts power at a frequency of 13.56 MHz to the precursor and nitrogen precursor gases disposed in the processing region 109 of the chamber 100 that is maintained at a pressure of less than about 400 Torr during the deposition process.

While the foregoing is directed to embodiments of the present invention, other and further embodiments of the invention may be devised without departing from the basic scope thereof, and the scope thereof is determined by the claims that follow.

1. A method of depositing a layer on one or more substrates, comprising:
flowing a first gas that comprises a first chemical element into a source region of a processing chamber;
heating a source material disposed in the source region, wherein the source material comprises a second chemical element;
forming a plasma over a surface of the heated source material to form a precursor gas that comprises the first chemical element and the second chemical element; and
flowing a second gas into the source region to deliver at least a portion of the formed precursor gas to a substrate processing region formed in the processing chamber.

2. The method of claim 1, wherein the second chemical element is selected from a group consisting of gallium (Ga), aluminum (Al) and indium (In).

3. The method of claim 1, wherein
the first chemical element is selected from a group consisting of chlorine (Cl), iodine (I) and bromine (Br); and
the second gas comprises a gas selected from a group consisting of nitrogen (N₂), helium (He) and argon (Ar).

4. The method of claim 1, further comprising:
flowing a third gas into the substrate processing region of the processing chamber while the at least a portion of the first gas is delivered into the processing region of the processing chamber, wherein the third gas comprises a gas selected from a group consisting of ammonia (NH₃) and hydrazine (N₂H₄).

5. The method of claim 1, wherein forming the plasma over the surface of the source material comprises biasing the heated source material relative to a ground.

6. The method of claim 5, further comprising:
flowing a third gas into the substrate processing region while the at least a portion of the first gas is delivered into the processing region of the processing chamber; and
forming a plasma over a surface of one or more substrates disposed in the processing region by providing electrical energy to an electrode that is in electrical communication with the processing region.

7. The method of claim 1, wherein forming the plasma over the surface of the source material comprises providing electrically energy through the heated source material.

8. The method of claim 7, wherein providing electrically energy comprises applying a voltage to the heated source material.

9. The method of claim 1, further comprising:
controlling a pressure in the source region to a pressure below the vapor pressure of the activated precursor gas.

10. The method of claim 1, wherein forming the plasma over the surface of the source material comprises electrically biasing a first electrode that is in electrical contact with the source material relative to an electrical ground.

11. The method of claim 10, wherein electrically biasing the first electrode further comprises delivering an applied voltage relative to the electrical ground at a frequency less than about 500 kHz.

12. An apparatus for forming a layer on one or more substrates, comprising:
a crucible disposed in a source region of a processing chamber, wherein the crucible has a first material collection region;
a first electrode disposed in the first material collection region of the crucible;
a power source coupled to the first electrode;
a heater configured to deliver energy to the first material collection region of the crucible; and
a substrate support disposed in a processing region of the processing chamber.

13. The apparatus of claim 12, further comprising:
a gas distribution showerhead disposed above the substrate support; and
a gas inlet ring disposed in the processing region between the gas distribution showerhead and the substrate support, wherein the gas inlet ring is fluidly coupled to the source region.

14. The apparatus of claim 12, wherein the crucible further comprises:
a second material collection region; and
a second electrode disposed in the second material collection region of the crucible, wherein the power source is configured to bias the first electrode relative to the second electrode.

15. The apparatus of claim 14, wherein the first material collection region is separated from the second material collection region by a wall that comprises a material selected from a group comprising quartz, boron nitride and silicon carbide.

16. The apparatus of claim 12, wherein the crucible further comprises a conductive element that is disposed adjacent to the first material collection region, and the power source is configured to bias the first electrode relative to the conductive element.

17. An apparatus for depositing a layer on one or more substrates, comprising:
a chamber body comprising one or more chamber walls that define a chamber processing region;
a precursor delivery source comprising:
a crucible disposed in a source region of the precursor deliver source having a first material collection region;
a first electrode disposed in the first material collection region of the crucible;
a power source coupled to the first electrode; and
gas delivery source configured to deliver a halogen gas to the source region; and
a gas distribution element positioned to distribute a process gas into the chamber processing region.

18. The apparatus of claim 17, further comprising:
a substrate support disposed within the chamber processing region opposite the gas distribution element.

19. The apparatus of claim 17, further comprising:
a second electrode disposed in a second material collection region that is formed in the crucible, wherein the power source is configured to bias the first electrode relative to the second electrode.

20. The apparatus of claim 19, wherein the first material collection region is separated from the second material collection region by a wall that comprises a material selected from a group comprising quartz, boron nitride and silicon carbide.

21. The apparatus of claim 17, wherein the crucible further comprises a conductive element that is disposed adjacent to the first material collection region, and the power source is configured to bias the first electrode relative to the conductive element.

22. The apparatus of claim 17, wherein the precursor deliver source further comprises a tube that fluidly couples the source region and the chamber processing region.
